(19) United States
(12) Patent Application Publication
(10) Pub. No.: US 2022/0268969 A1
(43) Pub. Date: Aug. 25, 2022

(54) LIGHT DIFFUSING LENS WITH SQUARE IRRADIATION DISTRIBUTION

(71) Applicant: HL OPTICS CO., LTD, Hwaseong-si (KR)

(72) Inventors: Seok Chae KO, Jecheon-si (KR); Jae Yu JUNG, Gwangju-si (KR); Kang Hyun LEE, Pyeongtaek-si (KR)

(21) Appl. No.: 17/207,279

(22) Filed: Mar. 19, 2021

(30) Foreign Application Priority Data
Feb. 23, 2021 (KR) 10-2021-0024188

(51) Int. Cl. G02B 3/04

(52) U.S. Cl. CPC G02B 3/04; G02B 2003/0093

(57) ABSTRACT

Disclosed is a light diffusing lens installed to cover an LED package mounted on a substrate, including a bottom surface which is an ellipse having a semi major axis and a semi minor axis, and a top surface which has a dome-shaped structure, wherein a Z segment function f(a) of the top surface line segment in a diagonal radius direction between the semi major axis and the semi minor axis is specified.

### CROSS-REFERENCE TO RELATED APPLICATION

This application claims priority to and the benefit of Korean Patent Application No. 10-2021-0024188, filed on Feb. 23, 2021, the disclosure of which is incorporated herein by reference in its entirety.

### TECHNICAL FIELD

The present disclosure relates to a light diffusing lens with square irradiation distribution.

### BACKGROUND

Backlight unit (BLU), which uses LEDs, applies a secondary lens individually for each LED for the purpose of light diffusion.

The purpose of using the diffusing lens is to diffuse the light of the LED in a uniform direction to prevent the occurrence of hot spots, which are parts brighter than dark parts or other parts.

In addition, the shape of the backlight unit is mainly a quadrangle such as a rectangle, and in a structure where the LEDs are arranged at regular intervals in the row and columns, the backlight unit provides a rectangular light distribution, thereby providing uniform surface light emission without occurrence of dark areas or hot spots.

Various techniques have been disclosed for forming a quadrangle light distribution on a plane using a diffusing lens.

Registered Patent No. KR10-1583647B (Light Guide Lens for LED, registered on Jan. 4, 2016) and Registered Patent No. KR10-1286705B (LIGHT SOURCE AND LENS FOR LIGHT SOURCE AND BACKLIGHT ASSEMBLY HAVING THE SAME, registered on Jul. 10, 2013) disclose related technologies.

The above information disclosed in this Background section is only for enhancement of understanding of the background of the invention and it may therefore contain information that does not form the prior art that is already known to a person of ordinary skill in the art.

### SUMMARY

Various aspects of the present invention are directed to providing a light diffusing lens with a square irradiation distribution that can flexibly cope with changes in spacing of LEDs installed in a backlight unit while maintaining a dome-shaped structure.

Specifically, the present disclosure is directed to providing a light diffusing lens that is easy to design and manufacture, and that can cope with various LED spacings by changing numerical values for a part of the entire structure. The present disclosure is further directed to a light diffusing lens with square light distribution by adjusting a z segment of an emitting surface in a diagonal direction.

An embodiment of the present invention provides a light diffusing lens installed to cover an LED package mounted on a substrate, including: a bottom surface which is an ellipse having a semi major axis and a semi minor axis, and a top surface which has a dome-shaped structure, wherein a Z segment function f(a) of the top surface line segment in a diagonal radius direction between the semi major axis and the semi minor axis may be defined by Equation 1 below:

Arₐ^{b}+Brₐ⁵+Crₐ⁴+Drₐ³+Erₐ²+Frₐ−0.5≤f(a)≤1.7Arₐ⁶+1.6Brₐ⁵+1.5Crₐ⁴+1.4Drₐ³+1.3Erₐ²+1.2Frₐ+0.5 [Equation 1]

Here, the A, B, C, D, E, and F each has a reference value of 0.000009, −0.00031, 0.004182, −0.02566, 0.0817, −0.135, and each is a real number within the range of 10% from the reference value, respectively.

In an embodiment of the present invention, a Z segment function f(x) of the top surface line segment in a semi major axis direction may be defined by Equation 2 below:

Arₓ⁶+Brₓ⁵+Crₓ⁴+Drₓ³+Erₓ²+Frₓ−0.5≤f(x)≤Arₓ+Brₓ⁵+Crₓ⁴+Drₓ³+Erₓ²+Frₓ+0.5 [Equation 2]

Here, the A, B, C, D, E, and F each has a reference value of 0.000009, −0.00031, 0.004182, −0.02566, 0.0817, −0.135, and each is a real number within the range of 10% from the reference value, respectively.

In an embodiment of the present invention, the Z segment function f(a) of the top surface line segment in the diagonal radius direction and the Z segment function f(x) of the top surface line segment in the semi major axis direction may be located opposite based on their respective median value when expressed as a graph.

In an embodiment of the present invention, the length of the semi minor axis of the bottom surface may be 88 to 90% of the length of the semi major axis of the bottom surface.

In an embodiment of the present invention, an incident surface in the shape of an elliptical cone may be located at the center of the bottom surface.

In an embodiment of the present invention, the semi major axis of a lower circumference of the incident surface may be in the same direction as the semi minor axis of the bottom surface, and the semi minor axis of the lower circumference of the incident surface may be in the same direction as the semi major axis of the bottom surface.

In an embodiment of the present invention, the length of the semi minor axis of the lower circumference of the incident surface may be 70 to 73% of the length of the semi major axis of the lower circumference of the incident surface.

The light diffusing lens according to the embodiment of the present invention is capable of forming a square light distribution while using a dome-shaped structure that is easy to design and manufacture, and thus, it is possible to provide light distribution without occurrence of dark parts and hot spots by being applied to a backlight unit.

In addition, the light diffusing lens according to the embodiment of the present invention can adjust the light distribution distance in the horizontal and vertical directions by changing the z segment in the diagonal direction of the light emitting surface, and thus, it is possible to easily cope with the spacing of the LED chips that are different for each backlight unit manufacturer.

### BRIEF DESCRIPTION OF THE DRAWINGS

The above and other aspects, features, and advantages of the present invention will become more apparent to those of ordinary skill in the art by describing embodiments thereof in detail with reference to the accompanying drawings, in which:

FIG. 1 is a perspective view of a light diffusing lens according to an embodiment of the present invention;

FIG. 2 is a top plan view of a light diffusing lens according to an embodiment of the present invention;

FIG. 3 is a bottom view of a light diffusing lens according to an embodiment of the present invention;

FIG. 4 is a cross-sectional view of a light diffusing lens according to an embodiment of the present invention;

FIG. 5 is a graph of a Z segment of a diagonal radius a;

FIG. 6 is a graph of the Z segment of a semi major axis X;

FIG. 7 is a ray tracing image according to an embodiment of the present invention;

FIG. 8 is an image distribution image according to an simulation of the present invention;

FIG. 9 is an image distribution image according to an simulation of the present invention applied to a BLU.

Description of Symbols

| | |
|---|---|
| 10: bottom surface | 20: top surface |
| 30: side surface | 40: incident surface |

### DETAILED DESCRIPTION OF EMBODIMENTS

Hereinafter, in order to fully understand the configuration and effects of the present invention, embodiments of the present invention will be described with reference to the accompanying drawings. However, the present invention is not limited to the embodiments disclosed below, and may be embodied in various forms and various modifications may be made. Rather, the description of embodiments of the present invention is provided so that this disclosure will be thorough and complete and will fully convey the concept of the invention to those of ordinary skill in the art. In the accompanying drawings, the size of the elements is enlarged compared to actual ones for the convenience of description, and the ratio of each element may be exaggerated or reduced.

Terms such as ‘first’ and ‘second’ may be used to describe various elements, but, the above elements should not be limited by the terms above. The terms may only be used to differentiate one element from another. For example, without departing from the scope of the present invention, ‘first element’ may be named ‘second element’ and similarly, ‘second element’ may also be named ‘first element.’ In addition, expressions in the singular include plural expressions unless explicitly expressed differently in context. Unless otherwise defined, the terminology used in the embodiments of the present invention may be interpreted as meanings commonly known to those of ordinary skill in the art.

One example of a technique forming a quadrangular light distribution includes forming a side surface of a light incident surface and a side surface of a second light emitting surface in a quadrangular shape, including a concave first light emitting surface and the second light emitting surface on the side parallel to an optical axis.

Another example of a technique includes forming an outer convex facet and an outer concave facet on a light emitting surface, and forming an incident surface with a combination of two surfaces which have different curvatures of an inner convex facet and an inner concave facet.

Since the above examples convert the shape of the lens into a shape other than a basic dome-shaped structure, a new mold design may be required to manufacture it, and it may not be easy to process due to the specificity of the shape may be considered.

In addition, it may not be possible to easily cope with the reduction in manufacturing cost of the backlight unit or the change in spacing of LEDs arranged in a square shape included in the backlight unit required by each display manufacturer.

That is, in the backlight unit, a plurality of LED chips are spaced apart in the horizontal and vertical directions and are arranged in a matrix. At this time, the distance in the horizontal direction and the distance in the vertical direction may be the same or different for each manufacturer. In addition, since different manufacturers have different specifications for the spacing between LED chips, it may be necessary to easily change the design to suit the product.

However, the foregoing examples are designed to meet a specific interval between LEDs, and it may be difficult to cope with a change in the interval between LEDs.

Hereinafter, a light diffusing lens according to embodiments of the present invention will be described in detail with reference to the drawings.

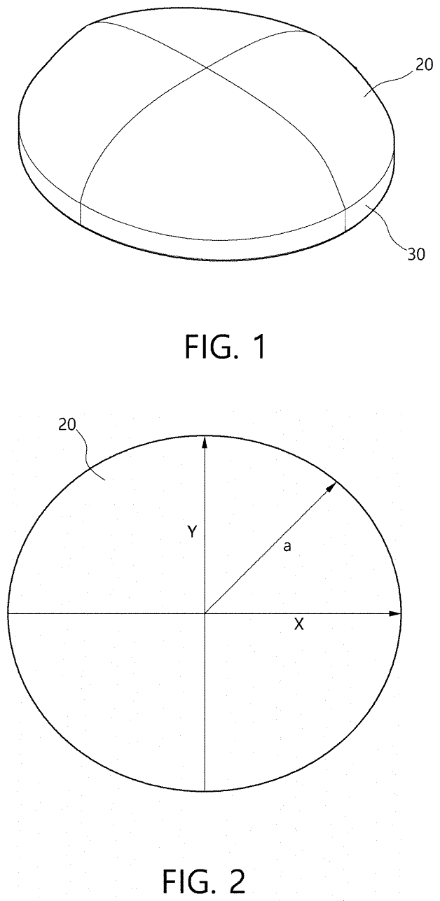

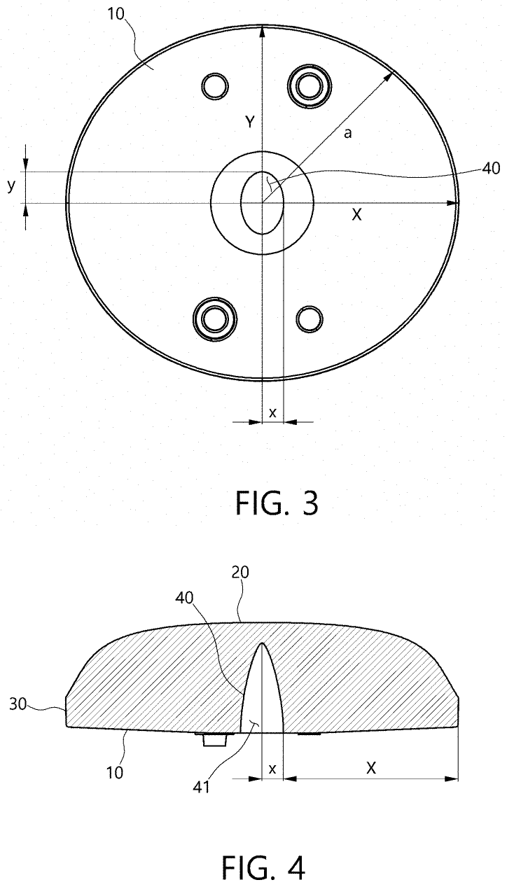

FIG. 1 is a perspective view of a light diffusing lens according to an embodiment of the present invention, FIG. 2 is a top plan view of FIG. 1, FIG. 3 is a bottom view of FIG. 1, and FIG. 4 is a cross-sectional side view in the long axis direction of FIG. 1.

Referring to FIGS. 1 to 4, respectively, the light diffusing lens according to embodiments of the present invention is a flat surface parallel to the ground, and includes a bottom surface 10 having a semi major axis X and a semi minor axis Y, a side surface 30 extending vertically upward with respect to the bottom surface 10 from the circumference of the bottom surface 10, and a top surface 20 that forms a dome-shaped light emitting surface at the upper portion of the side surface 30, and an incident surface 40 whose shape is determined by an accommodating groove 41 formed upward from the center of the bottom surface 10.

Hereinafter, the configuration and operation of the light diffusing lens according to embodiments of the present invention configured as described above will be described in more detail.

First, according to embodiments of the present invention, a single medium solid lens has a bottom surface 10, a top surface 20, and a side surface 30.

The bottom surface 10 is a flat surface and has an elliptical structure having a semi major axis X and a semi minor axis Y.

In this case, the length of the semi minor axis Y is set to be 88 to 90% of the length of the semi major axis X. The length of a diagonal radius a, a radius between the semi minor axis Y and the semi major axis X, is naturally longer than the semi minor axis Y and shorter than the semi major axis X.

The accommodating groove 41 is formed upward in the center of the bottom surface 10, and the lens according to embodiments of the present invention may be fixedly installed on a substrate on which an LED chip is mounted so that the LED chip is located in the accommodating groove 41.

According to the formation of the accommodating groove 41, an interface with the medium becomes the incident surface 40 through which the light of the LED is incident.

A lower circumference of the incident surface 40 is in the form of an ellipse having a semi major axis y and a semi minor axis x on a plane. That is, the entrance side of the accommodating groove 41 is elliptical. The semi minor axis x of the incident surface 40 is set to be 70 to 73% of the semi major axis y.

In this case, the entrance side semi major axis y of the accommodating groove 41 is the same direction as the semi minor axis Y of the bottom surface 10, the entrance side semi minor axis x of the accommodating groove 41 is the same direction as the semi major axis X of the bottom surface 10.

That is, the elliptical shape of the bottom surface 10 and the elliptical shape of the accommodating groove 41 are in the form rotated 90 degrees clockwise or counterclockwise on a plane.

As described above, embodiments of the present invention provide a structure suitable for forming a rectangular light distribution by using an incident surface 40 having a semi major axis in a direction different from that of the bottom surface 10.

The circumference of the bottom surface 10 extends so that the side surface 30 upwardly forms an angle with the bottom surface 10 to be 90 degrees (vertical).

The top surface 20 has a dome-shaped structure, and the circumference has a shape connected to the upper end of the side surface 30.

Accordingly, when only the circumferential portion of the top surface 20 is considered, the circumference of the top surface 20 becomes elliptical in the same ratio as the bottom surface 10.

That is, it has an elliptical circumference having a semi major axis X and a semi minor axis Y.

As a characteristic structure according to embodiments of the present invention, the top surface 20, which is a light emitting surface, has different curvatures in the direction of the diagonal radius a and the direction of the semi major axis X and the semi minor axis Y.

That is, the shape of the light distribution may be adjusted by adjusting the curvature of the top surface 20 in the diagonal radius a direction.

The definition of the diagonal radius (a) is a radial direction in a direction in which the angle between each of the semi major axis X and the semi minor axis Y is 45 degrees, not an arbitrary angular direction radius between the semi major axis X and the semi minor axis Y.

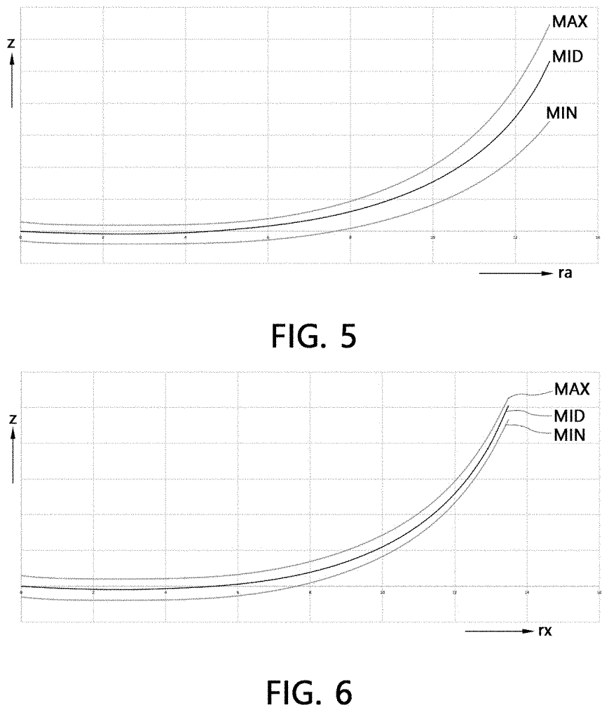

FIG. 5 is a graph of a Z segment of a diagonal radius a.

Here, the segment is a term that defines the shape of a typical lens, defining a line segment of a fan shape. In usual, the Z segment is defined as a multi-order function depending on the shape of the lens.

The function f(a) of the Z segment of the diagonal radius a of FIG. 5 may be defined by Equation 1 below.

Arₐ^{b}+Brₐ⁵+Crₐ⁴+Drₐ³+Erₐ²+Frₐ−0.5≤f(a)≤1.7Arₐ⁶+1.6Brₐ⁵+1.5Crₐ⁴+1.4Drₐ³+1.3Erₐ³+1.2Frₐ+0.5 [Equation 1]

As such, the Z-segment function f(a) of the diagonal radius a may be expressed as a sixth-order function of the variable rₐ.

In Equation 1 above, the constants A, B, C, D, E, and F are real numbers, respectively, and are assumed to be in the range of ±10% based on the reference values in Table 1 below.

For example, A has a reference value of 0.000009, which is a real number between maximum 0.0000099 and minimum 0.0000081.

In FIG. 5, the maximum value MAX is a graph when f(a) is 1.7Arₐ⁶+1.6Brₐ⁵+1.5Crₐ⁴+1.4Drₐ³+1.3Erₐ²+1.2Frₐ+0.5, and the minimum value MIN is a graph when f(a) is Arₐ⁶+Brₐ⁵+Crₐ⁴+Drₐ³+Erₐ²+Frₐ−0.5.

FIG. 6 is a graph of the Z segment of a semi major axis X, and the Z segment function f(x) may be defined by Equation 2 below.

Arₓ⁶+Brₓ⁵+Crₓ⁴+Drₓ³+Erₓ²+Frₓ−0.5≤f(x)≤Arₓ+Brₓ⁵+Crₓ⁴+Drₓ³+Erₓ²+Frₓ+0.5 [Equation 2]

In Equation 2 above, constants A, B, C, D, E, and F are the same as described above.

Table 1 below describes the reference values of each constant.

TABLE 1

| Constant | Reference value |
|---|---|
| A | 0.000009 |
| B | −0.00031 |
| C | 0.004182 |
| D | −0.02566 |
| E | 0.0817 |
| F | −0.135 |

As described above, according to embodiments of the present invention, a quadrangle light distribution may be provided by using the shape of the diagonal radius a of the Z segment function different from the semi major axis X and the semi minor axis Y.

According to embodiments of the present invention, a quadrangle light distribution may be formed by applying a smoother curvature of the line segment of the top surface 20 in the diagonal radius a direction compared to the line segment of the top surface 20 in the semi major axis X direction.

In FIG. 6 the maximum value MAX is a graph when f(x) is Arₓ⁶+Brₓ⁵+Crₓ⁴+Drₓ³+Erₓ²+Frₓ+0.5, and the minimum value MIN is a graph when f(x) is Arₓ⁶+Brₓ⁵+Crₓ⁴+Drₓ³+Erₓ²+Frₓ−0.5.

In this case, if the value of the Z segment function f(x) in the semi major axis X direction is close to the maximum value MAX based on the median value MID, the Z segment function f(a) in the diagonal radius a direction is produced by selecting a value close to the minimum value MIN, and conversely, if the value of the Z segment function f(x) in the semi major axis X direction is close to the minimum value MIN based on the median value MID, the Z segment function f(a) in the diagonal radius a direction is produced by selecting a value close to the maximum value MAX.

That is, the Z segment function f(x) in the semi major axis X direction and the Z segment function f(a) in the diagonal radius a direction selects functions located at different positions based on the median value MID to process the lens.

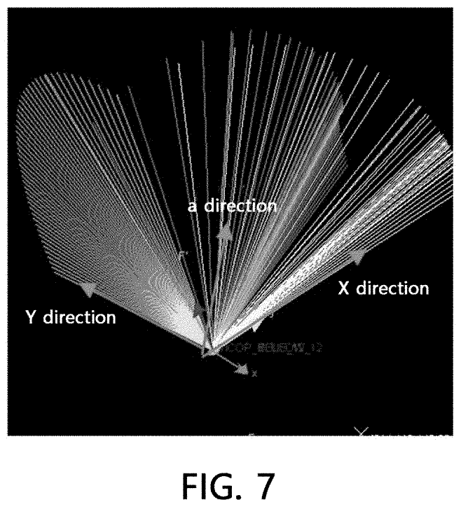

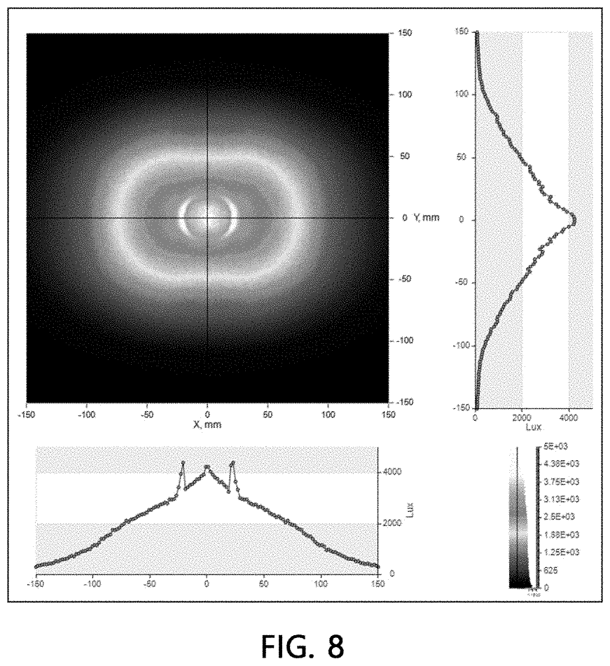

FIG. 7 is a ray tracing image according to an embodiment of the present invention, and FIG. 8 is an image distribution image according to a simulation of embodiments of the present invention.

As shown in these FIGS. 7 and 8, according to embodiments of the present invention, a light distribution in which the semi major axis X and the semi minor axis Y are clearly revealed may be provided, but a rectangular light distribution by adjusting the Z segment in the diagonal radius a direction may be provided.

To this end, as described above, the incident surface 40 has a conical structure with an ellipse at the bottom, so that diffusion in the direction of the semi major axis X is better, and by placing a difference at the Z segment of the semi major axis X and the Z segment of the diagonal radius to form a light distribution close to the corner of the square in the diagonal radius a direction, it may be possible to prevent the occurrence of dark parts or hot spots when applied to the BLU.

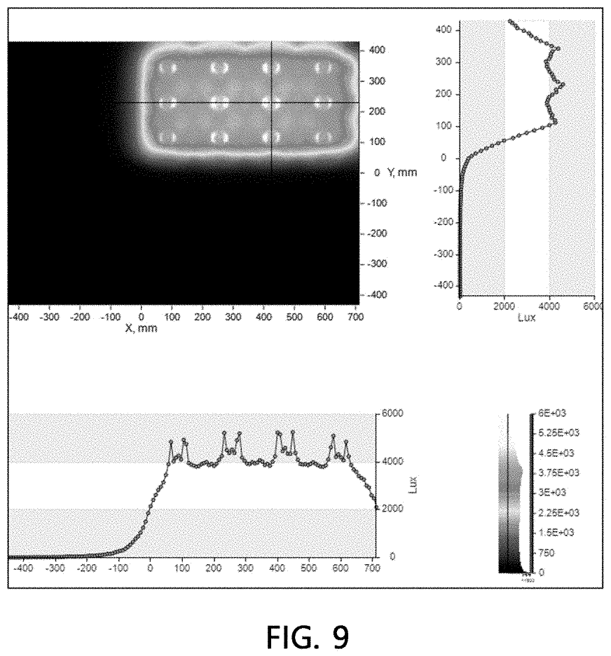

FIG. 9 is an image distribution image according to a simulation of embodiments of the present invention applied to a BLU.

As shown in FIG. 9, it may be possible to prevent the occurrence of dark parts by arranging the light diffusing lenses according to embodiments of the present invention and providing square light distribution in each lens, and prevent the formation of hot spots by preventing light from overlapping as much as possible.

While this invention has been described in connection with what is presently considered to be embodiments, those skilled in the art may understand that the invention is not limited to the disclosed embodiments, but, on the contrary, is intended to cover various modifications and equivalent arrangements included within the spirit and scope of the appended claims. Accordingly, the scope of the present invention shall be determined only according to the attached claims.

What is claimed is:

1. A light diffusing lens installed to cover an LED package mounted on a substrate, comprising:
a bottom surface which is an ellipse having a semi major axis and a semi minor axis; and
a top surface which has a dome-shaped structure;
wherein a Z segment function f(a) of the top surface line segment in a diagonal radius direction between the semi major axis and the semi minor axis is defined by Equation 1 below:
Arₐ^{b}+Brₐ⁵+Crₐ⁴+Drₐ³+Erₐ²+Frₐ−0.5≤f(a)≤1.7Arₐ⁶+1.6Brₐ⁵+1.5Crₐ⁴+1.4Drₐ³+1.3Erₐ²+1.2Frₐ+0.5 [Equation 1]
wherein the A, B, C, D, E, and F each has a reference value of 0.000009, −0.00031, 0.004182, −0.02566, 0.0817, −0.135, and each is a real number within the range of 10% from the reference value, respectively.

2. The lens of claim 1, wherein a Z segment function f(x) of the top surface line segment in a semi major axis direction is defined by Equation 2 below:
Arₓ⁶+Brₓ⁵+Crₓ⁴+Drₓ³+Erₓ²+Frₓ−0.5≤f(x)≤Arₓ⁶+Brₓ⁵+Crₓ⁴+Drₓ³+Erₓ²+Frₓ+0.5 [Equation 2]
wherein the A, B, C, D, E, and F each has a reference value of 0.000009, −0.00031, 0.004182, −0.02566, 0.0817, −0.135, and each is a real number within the range of 10% from the reference value, respectively.

3. The lens of claim 2, wherein the Z segment function f(a) of the top surface line segment in the diagonal radius direction and the Z segment function f(x) of the top surface line segment in the semi major axis direction are located opposite based on their respective median value when expressed as a graph.

4. The lens of claim 1, wherein the length of the semi minor axis of the bottom surface is 88 to 90% of the length of the semi major axis of the bottom surface.

5. The lens of claim 1, wherein an incident surface in the shape of an elliptical cone is located at the center of the bottom surface.

6. The lens of claim 5, wherein the semi major axis of a lower circumference of the incident surface is in the same direction as the semi minor axis of the bottom surface, and the semi minor axis of the lower circumference of the incident surface is in the same direction as the semi major axis of the bottom surface.

7. The lens of claim 6, wherein the length of the semi minor axis of the lower circumference of the incident surface is 70 to 73% of the length of the semi major axis of the lower circumference of the incident surface.

8. The lens of claim 2, wherein an incident surface in the shape of an elliptical cone is located at the center of the bottom surface.

9. The lens of claim 8, wherein the semi major axis of a lower circumference of the incident surface is in the same direction as the semi minor axis of the bottom surface, and the semi minor axis of the lower circumference of the incident surface is in the same direction as the semi major axis of the bottom surface.

10. The lens of claim 9, wherein the length of the semi minor axis of the lower circumference of the incident surface is 70 to 73% of the length of the semi major axis of the lower circumference of the incident surface.
